(19) United States
(12) Patent Application Publication
(10) Pub. No.: US 2016/0108718 A1
(43) Pub. Date: Apr. 21, 2016

(54) HIGHLY PRESSURE-RESISTANT COOLING CONTAINER FOR SENSOR AND UNDERGROUND PROBING EQUIPMENT

(71) Applicant: JAPAN OIL, GAS AND METALS NATIONAL CORPORATION, Tokyo (JP)

(72) Inventors: Tsunehiro Hato, Yokohama-shi (JP); Akira Tsukamoto, Yokohama-shi (JP); Keiichi Tanabe, Kawasaki-shi (JP)

(73) Assignee: JAPAN OIL, GAS AND METALS NATIONAL CORPORATION, Tokyo (JP)

(21) Appl. No.: 14/978,757

(22) Filed: Dec. 22, 2015

Related U.S. Application Data
(63) Continuation of application No. PCT/JP2014/066276, filed on Jun. 19, 2014.

(30) Foreign Application Priority Data
Jun. 27, 2013 (JP) 2013-134809

(51) Int. Cl. E21B 47/01; G01R 33/035; G01R 33/00; G01V 3/08

(52) U.S. Cl. CPC E21B 47/011; G01V 3/08; G01R 33/0354; G01R 33/0047

(57) ABSTRACT

To cool a SQUID to a stable operational temperature for a long period of time under high pressure that exceeds 1.0 MPa, a highly pressure-resistant cooling container for a sensor includes a pressure-resistant airtight container having a pressure-resistance performance of 1.0 MPa or higher, a phase transition coolant insulating container contained within the pressure-resistant airtight container, and a tube for releasing a phase transition coolant having a pressure-resistance performance of 1.0 MPa or higher and connected to the pressure-resistant airtight container.

### CROSS-REFERENCE TO RELATED APPLICATIONS

This application is a continuation of International Application No. PCT/JP2014/066276, filed on Jun. 19, 2014, now pending, herein incorporated by reference. Further, this application is based upon and claims the benefit of priority from the prior Japanese Patent Application No. 2013-134809, filed on Jun. 27, 2013, entire contents of which are incorporated herein by reference.

### TECHNICAL FIELD

The present invention relates to a highly pressure-resistant cooling container for a sensor and an underground probing equipment, and in particular to a highly pressure-resistance structure of a cooling container that contains a sensor using a superconducting quantum interference device (SQUID) to be used for an underground resource-probing equipment, for example.

### BACKGROUND ART

A SQUID using a high temperature superconductor has been utilized in the sensor for an underground resource-probing equipment, a geomagnetic observing device, a non-destructive inspection device and the like. These sensors using a SQUID need to be cooled with liquid nitrogen and are required to have a low amount of noise. In particular, an underground resource-probing equipment where a SQUID for logging is inserted in a bowling casing at a depth that exceeds 1,000 m is important for monitoring the injection of CO₂ for a technology for increasing oil production or a technology for monitoring shale gas.

In accordance with a simple conventional technology for pumping up oil, for example, only approximately 30% of the deposits can be pumped up. In recent years, however, an enhanced oil recovery (EOR) technology for increasing the oil recovery efficiency by injecting highly pressurized CO₂ into an oil containing rock layer has been developed. The oil recovery factor greatly increases to approximately 90% by using the EOR technology.

In accordance with a conventional technology using artificial earthquake wave vibrations, however, it cannot be precisely detected in which regions of and to which extent an oil containing rock layer is impregnated with CO₂ or water. Therefore, two deep holes that reach the oil containing rock layer are drilled, one for an exciting coil that generates a magnetic field and the other for a magnetic sensor, so that the amount of impregnation with water or CO₂ can be measured by detecting the distribution of the resistivity in the layer through a change in the magnetic field created by the exciting coil placed outside by means of a magnetic sensor, such as of an electromagnetic coil contained in a bowling casing in a pipe form made of carbon steel, at a location away from the magnetic field. Thus, the change in the magnetic field is measured through a conductive casing, and therefore, high frequency components attenuate, which causes such a problem that high sensitivity cannot be gained with a conventional magnetic sensor that detects an electromotive force due to electromagnetic induction. In contrast, a SQUID utilizing superconductivity is highly sensitive and makes it possible to measure a static magnetic field, which makes it easy to measure through the casing. In some cases, however, measurement is carried out in a location of which the depth exceeds 3,000 m underground, and for this a container that can bear a pressure of 30 MPa is required.

It is also necessary to maintain the temperature in lower than the critical temperature for superconductivity in order to make the operation of a SQUID stable for a long period of time. When the pressure within the airtight container that contains the SQUID increases, however, the boiling point of liquid nitrogen rises, which makes it impossible to maintain the critical temperature for superconductivity.

FIG. 15 is a graph illustrating the dependency of the pressure on the boiling point of liquid nitrogen, where the boiling point rises as the pressure increases. As is clear from the figure, a temperature of 80 K or lower cannot be maintained, which means that it is difficult to operate a high temperature superconducting SQUID, unless the pressure within the airtight container is maintained at 0.13 MPa or lower.

### CITATION LIST

### Non-Patent Literature

Non-Patent Literature 1: Tokugikon (Patent Office Society) No. 264, pp. 92-100, Jan. 30, 2012

### SUMMARY OF INVENTION

### Problems to be Solved by the Invention

There are no conventional SQUIDs using a high temperature superconductor that are usable in such an environment where the pressure exceeds 1.0 MPa, which corresponds to a depth of 100 meters underwater. In addition, a technology for cooling a SQUID within an airtight container has not been developed. In the case where a refrigerator is used, for example, electromagnetic noise and the noise from vibrations are created, which makes it difficult for the SQUID to exercise its high sensitivity.

In the case where liquid nitrogen is used, the volume expands approximately 700 times greater through evaporation, and therefore, the pressure increases within the airtight container and the boiling point of the liquid nitrogen rises. As a result, as illustrated in FIG. 15, the boiling point exceeds 80 K when the pressure exceeds 0.13 MPa, which means that the temperature exceeds the critical temperature for superconductivity, and thus, it is difficult to operate the SQUID for a long period of time.

Therefore, an object of the present invention is to provide a highly pressure-resistant cooling container which makes it possible to continuously cool a SQUID to a stable operational temperature for a long period of time under high pressure that exceeds 1.0 MPa.

### Means for Solving the Problems

One aspect of the disclosed invention provides a highly pressure-resistant cooling container for a sensor characterized by being provided with: a pressure-resistant airtight container having a pressure-resistance performance of 1.0 MPa or higher; a phase transition coolant insulating container contained within the pressure-resistant airtight container; and a tube for releasing a phase transition coolant having a pressure-resistance performance of 1.0 MPa or higher and connected to the pressure-resistant airtight container.

Another aspect of the disclosed invention provides an underground probing equipment characterized in that a phase transition coolant is contained inside the above-described phase transition coolant insulating container in the highly pressure-resistant cooling container for a sensor, and a sensor is immersed in the above-described phase transition coolant.

### ADVANTAGEOUS EFFECTS OF THE INVENTION

The disclosed highly pressure-resistant cooling container for a sensor and the underground probing equipment make it possible to continuously cool a SQUID at a stable operational temperature for a long period of time under a high pressure that exceeds 1.0 MPa.

### BRIEF DESCRIPTION OF DRAWINGS

FIGS. 1A and 1B are diagrams illustrating a highly pressure-resistant cooling container for a sensor according to an embodiment of the present invention;

FIG. 2 is a diagram illustrating an underground probing equipment according to an embodiment of the present invention;

FIG. 3 is a perspective diagram illustrating a main portion of the SQUID underground resource-probing equipment according to Example 1 of the present invention;

FIG. 4 is a graph illustrating the results of calculation in terms of the relationship between the inner diameter and the length of a releasing tube and the increase in the pressure due to the resistance of evaporated nitrogen;

FIG. 5 is a perspective diagram illustrating a main portion of the SQUID underground resource-probing equipment according to Example 2 of the present invention;

FIG. 6 is a perspective diagram illustrating a main portion of the SQUID underground resource-probing equipment according to Example 3 of the present invention;

FIG. 7 is a perspective diagram illustrating a main portion of the SQUID underground resource-probing equipment according to Example 4 of the present invention;

FIG. 8 is a perspective diagram illustrating a main portion of the SQUID underground resource-probing equipment according to Example 5 of the present invention;

FIG. 9 is a perspective diagram illustrating a main portion of the SQUID underground resource-probing equipment according to Example 6 of the present invention;

FIG. 10 is a perspective diagram illustrating a main portion of the SQUID underground resource-probing equipment according to Example 7 of the present invention;

FIG. 11 is a perspective diagram illustrating a main portion of the SQUID underground resource-probing equipment according to Example 8 of the present invention;

FIG. 12 is a graph illustrating the time difference between the increase in the pressure and the increase in the temperature;

FIG. 13 is a perspective diagram illustrating a main portion of the SQUID underground resource-probing equipment according to Example 9 of the present invention;

FIG. 14 is a perspective diagram illustrating a main portion of the SQUID underground resource-probing equipment according to Example 10 of the present invention; and

FIG. 15 is a graph illustrating the dependency of the pressure on the boiling point of liquid nitrogen.

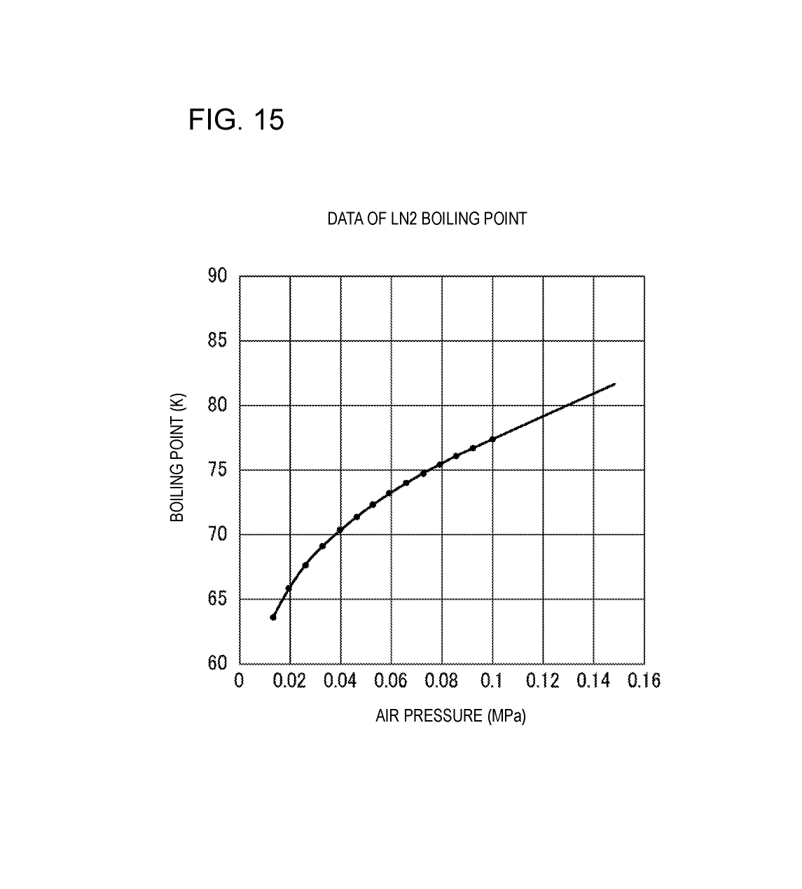

### DESCRIPTION OF EMBODIMENTS

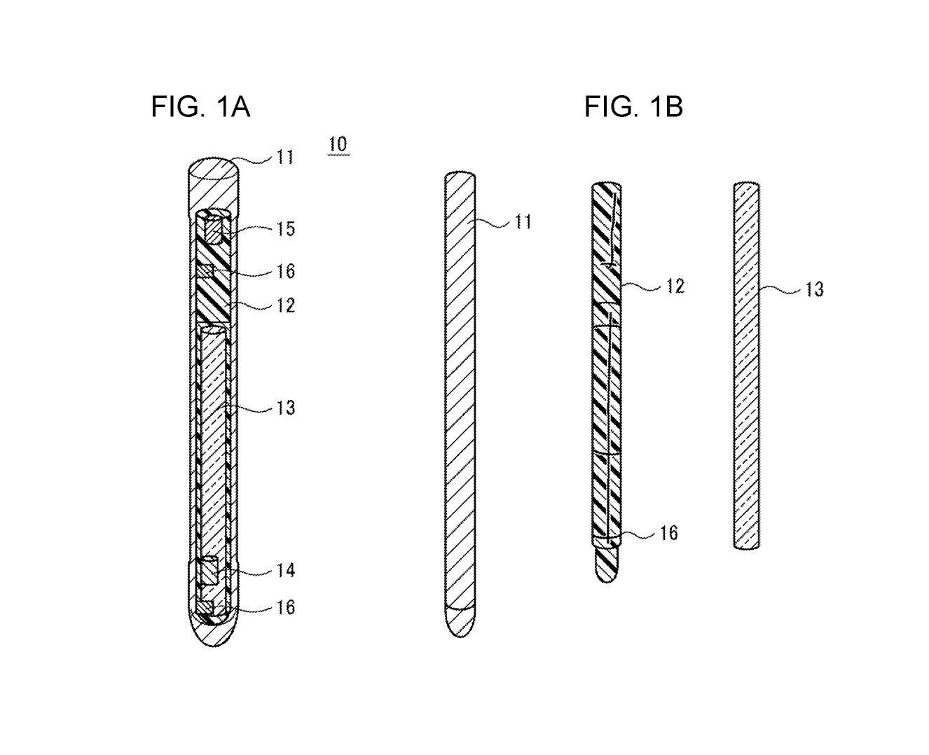

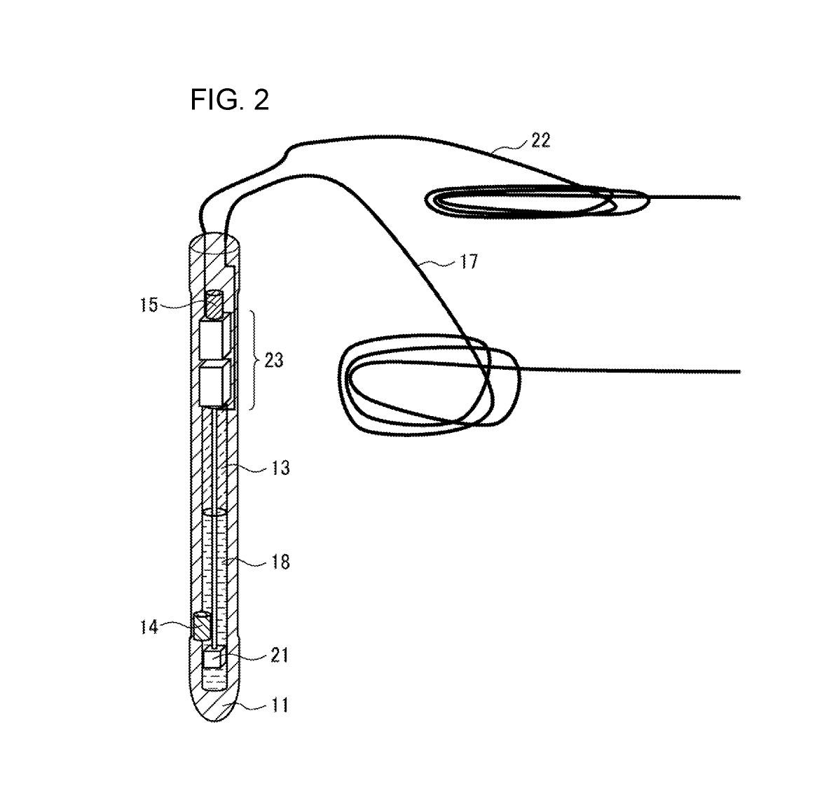

Here, the highly pressure-resistant cooling container for a sensor and the underground probing equipment according to an embodiment of the present invention are described in reference to FIGS. 1A through 2. FIGS.1A and 1B are diagrams illustrating the highly pressure-resistant cooling container for a sensor according to an embodiment of the present invention. FIG. 1A is a perspective diagram illustrating a main portion, and FIG. 1B is an exploded perspective diagram.

As illustrated in the figures, a highly pressure-resistant cooling container for a sensor 10 is provided with a pressure-resistant airtight container 11 having a pressure-resistance performance of 1.0 MPa or higher, a protective interior 12 contained inside the pressure-resistant airtight container 11, and a phase transition coolant insulating container 13 contained inside the protective interior 12. In addition, a thermometer 14 is provided inside the phase transition coolant insulating container 13. A pressure sensor 15 is provided in the vicinity of the top of the protective interior 12, and at the same time, a water leak detector 16 is provided in the outer periphery of the protective interior. As described below, a tube for releasing a phase transition coolant (17) having a pressure-resistance performance of 1.0 MPa or higher is connected to this pressure-resistant airtight container so as to provide the highly pressure-resistant cooling container for a sensor 10.

A non-magnetic material having a heat resistance of 200° C. or higher is used for the pressure-resistant exterior for implementing the pressure-resistance performance of 1.0 MPa or higher of the pressure-resistant airtight container 11 and the tube for releasing a phase transition coolant (17). Materials such as a waterproof engineering plastic, a carbon and glass fiber reinforced plastic, ceramics, titanium, aluminum and stainless steel can be used as the non-magnetic material. When the depth is great underground, the environmental temperature is high, and a case where the temperature exceeds 200° C. can be assumed. Therefore, it is necessary for the plastic to be used to have high heat resistance such as of a PEEK (polyetheretherketone) material, PPS (poly phenylene sulfide), RENY (50% glass fiber reinforced polyamide MXD6 (registered trademark)), and CFRP (carbon fiber reinforced plastics).

Not only the main body of the container, but also the sealing material such as of a gasket and an O-ring are required to be made of a heat resistant material. It is effective for the sealing material to be a Naflon (registered trademark) gasket or a Naflon (registered trademark) paste and for the O-ring to be made of a fluorine rubber that is heat resistant at a temperature that exceeds 200° C. or a high performance rubber (perfluororubber) that is heat resistant at a temperature that exceeds 300° C.

The phase transition coolant insulating container 13 is typically a glass dewar, where it is desirable to provide a metal plating of which the thickness is 2 μm or less, for example, a silver plating, in the vacuum layer on the inside in order to increase the mechanical strength, and at the same time to prevent heat from flowing in. An excessively thick plating is not preferable due to the risk of generating an induction current accompanying a change in the magnetic field. In addition, crystal glass and Pyrex (registered trademark) can be used as the glass. Though such a glass dewar is weak against impacts, it has a small amount of outgassing as compared to plastic materials, and thus, the performance is stable for a long period of time without maintenance, and at the same time, the heat influx is small, which makes it possible to maintain a small volume of a phase transition coolant in a liquid state for a long period of time.

It is also desirable for the phase transition coolant insulating container 13 to be a glass vacuum dewar of which the length is preferably 10 to 50 times greater, and more preferably 10 to 30 times greater than the inner diameter. Thus, the heat influx can be reduced by using a long and deep dewar. In the case where liquid nitrogen is used as the phase transition coolant, for example, a dewar of which the length is more than 30 times greater than the inner diameter is easily broken due to vibrations when being transported on its side, though the shape is advantageous in terms of the heat flow. Furthermore, a dewar of which the length is more than 50 times greater than the inner diameter allows the boiling point of liquid nitrogen to be high due to the pressure of the liquid nitrogen, and there is a risk of the operation of the SQUID being unstable. Incidentally, it was confirmed that liquid nitrogen can be maintained in a room temperature environment for 30 hours or more in an experiment using a Pyrex (registered trademark) vacuum dewar having an inner diameter of 40 mm and a length of 500 mm. The increase in the pressure can be reduced by reducing the amount of evaporation of the liquid nitrogen, which makes it possible for the diameter of the tube for releasing a nitrogen gas to be smaller.

It is also desirable for an RF shield for shielding a high frequency of 50 KHz or higher to be provided inside the pressure-resistant airtight container 11. In the case where a non-conductive material such as ceramics or a plastic, or a high resistance metal that easily allow a high frequency to transmit is used for the exterior, the SQUID operation sometimes becomes difficult due to RF noise, and in such a case, it becomes necessary for an appropriate RF shield to be contained. The material for the RF shield includes a cloth coated with aluminum or plated with a metal (such as Ni'Cu plated), and a mesh formed of metal wires (such as of copper, silver and phosphor bronze) depending on the frequency to be shielded. In particular, Ni—Cu plating allows for the generation of an induction current of which the attenuation constant is approximately 10⁻⁷ sec due to the great resistance, which is smaller by approximately 4 digits as compared to the case of Al with an attenuation constant of approximately 10⁻³ sec, and therefore is appropriate because of the small affects from the induction current. Here, a power transmission line that causes an RF noise of 100 KHz is a typical example of an RF source, while a machine that operates in proximity also becomes an RF source. The RF shield is made of approximately three to nine layers that are layered on top of each other depending on the application, where the thickness of one layer is approximately 100 μm.

In addition, it is desirable to provide a phase transition coolant absorbent inside the phase transition coolant insulating container 13. There are many cases where the underground probing equipment, typically the SQUID underground probing equipment, is inclined in the underground source probe. In the case where the phase transition coolant insulating container 13 is inclined, the phase transition coolant such as liquid nitrogen easily spills over from the inside of the liquid nitrogen dewar 13. The phase transition coolant absorbent is effective in preventing this spilling over. In addition, bubbling due to the evaporation of the phase transition coolant sometimes induces vibrations to the SQUID probe, which may cause noise. Though such noise from the vibrations specifically prevents the low frequency from being measured, the contained phase transition coolant absorbent absorbs the vibration due to the bubbling, and thus has an effect of preventing noise from being generated. A polyvinyl alcohol (PVA) sponge or a melamine foam can be effectively used as the phase transition coolant absorbent, particularly as the liquid nitrogen absorbent. Here, a PVA sponge can be formed so as to have pores of which the size can be precisely designed, and therefore, the amount of liquid nitrogen to be sucked out can be controlled.

FIG. 2 is a diagram illustrating the underground probing equipment according to an embodiment of the present invention, where the phase transition coolant insulating container 13 in the highly pressure-resistant cooling container for a sensor in FIG. 1A is filled with a phase transition coolant 18 such as liquid nitrogen, in which a sensor 21 such as a SQUID is immersed, and at the same time, a cable 22 for inputting/outputting a signal is connected to the pressure-resistant airtight container 11. A number of signal wires are contained inside the cable 22 for inputting/outputting a signal. In the case where the probing depth is deep, optical fibers are used as the signal wires. In addition, a sensor control system 23 such as an FLL (flux locked loop) circuit is provided between the sensor 21 and the cable 22 for inputting/outputting a signal. Though the size of the pressure-resistant airtight container 11 varies depending on the application, in general, the length is 1 m to 2.5 m and the outer diameter is approximately 80 mm to 200 mm. In addition, the cable 22 for inputting/outputting a signal generally has an outer diameter of approximately 15 mm. In the case where the sensor is a SQUID, six signal lines per channel of the SQUID need to be contained within the cable 22 for inputting/outputting a signal, and in addition, signal lines to a sensor for sensing the position are necessary, and therefore, it is general for approximately 20 or more signal lines to be contained.

Furthermore, the tube for releasing a phase transition coolant 17 may be formed as an aggregate of a number of tubes, which may be integrated while being intertwined such as cable wires, in order to increase the mechanical strength. Moreover, the tube for releasing a phase transition coolant 17 may be contained inside the cable 22 for inputting/outputting a signal , which further increases pressure resistance, and thus is appropriate for probing at a deep depth.

It is also desirable to provide a pressure-maintaining mechanism which maintains the pressure inside the tube for releasing a phase transition coolant at a negative pressure relative to the pressure inside the pressure-resistant airtight container 11, and which maintains the pressure inside the pressure-resistant airtight container 11 at 0.04 MPa to 0.13 MPa. Here, 0.04 MPa corresponds to the air pressure under which the boiling point of liquid nitrogen is approximately 70 K, while 0.13 MPa corresponds to the air pressure under which the boiling point of liquid nitrogen is approximately 80 K.

It is also desirable for the detected output from the pressure sensor 15 provided inside the pressure-resistant airtight container 11 to be feedback controlled so as to maintain the temperature inside the pressure-resistant airtight container 11 at a constant. The increase in the temperature is gradual as compared to the increase in the pressure, and therefore, a dramatic increase in the pressure cannot be handled in the case where the temperature is controlled by sensing the temperature. Accordingly, a dramatic displacement of the pressure can be handled by controlling the temperature through the control of the pressure following the detection of a change in the pressure.

For this purpose, an opening and a closing mechanism for opening and closing a valve may be provided in the tube for releasing a phase transition coolant 17. Alternatively, some from among a number of tubes for releasing a phase transition coolant 17 that are contained in the cable 22 for inputting/outputting a signal may be used as tubes for releasing a phase transition coolant in a state of being open to the air all the time, while the other tubes may be maintained at a negative pressure on the inside and connected via a valve.

Thus, the tube for releasing a phase transition coolant is connected to the pressure-resistant airtight container 11 in order to prevent the pressure from increasing within the container, and therefore, the pressure within the pressure-resistant airtight container 11 can be maintained at a constant, which makes it possible for the sensor such as a SQUID to operate under a high pressure. In particular, a dewar having a small opening can be used to reduce the heat influx so that a small volume of a phase transition coolant such as liquid nitrogen can be maintained for a long period of time. At the same time, the tube for releasing a phase transition coolant can have an inner diameter that is appropriate for the amount of evaporation and the length of the releasing tube, and thus, it is easy to control the inner pressure. Here, such an underground probing equipment can be used not only for underground resource probing, but also for probing the state of the underground bedrock beneath a high-rise building. Accordingly, the tube for releasing a phase transition coolant 17 and the cable 22 for inputting/outputting a signal have a length of 20 m to 4,000 m, and in the case of 4,000 m, resistance to the pressure of 40 MPa or greater is necessary.

According to the embodiment of the present invention, logging becomes possible in the underground probing equipment due to a sensor such as a SQUID within the casing, which has been difficult according to the prior art. In particular, a SQUID is not only highly sensitive, but also can allow three-dimensional data having directionality to be acquired while saving space. Any conventional element would not have been able to do this, and therefore, it becomes possible to provide a revolutionary probing and monitoring technology through EOR for collecting resources including oil and natural gas, and thus, the degree of technical contribution of the invention to the field of resource and energy collecting is extremely high.

### EXAMPLE 1

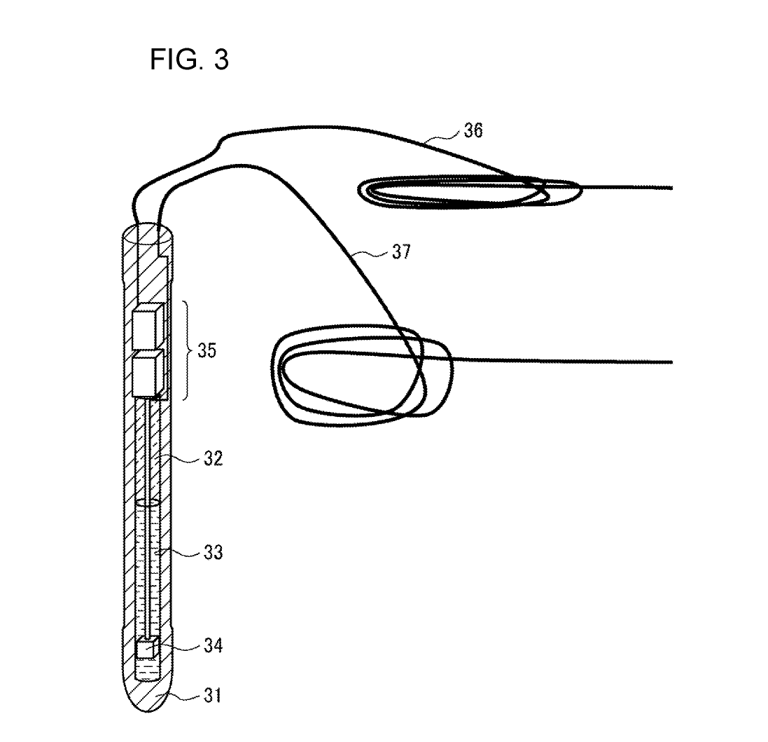

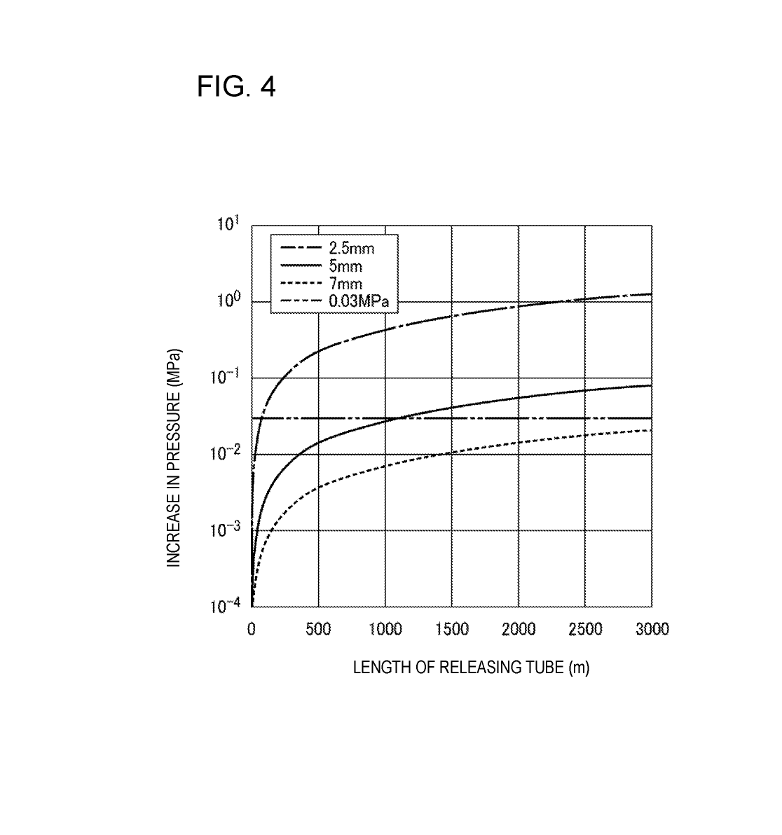

Next, the SQUID underground resource probing equipment according to Example 1 of the present invention is described in reference to FIGS. 3 and 4. The example here is described under the assumption that the probe depth is 20 m to 1,000 m. FIG. 3 is a perspective diagram illustrating a main portion of the SQUID underground resource probing equipment according to Example 1 of the present invention, where a dewar for liquid nitrogen 32 made of Pyrex (registered trademark) is contained within a highly pressure-resistant heatproof airtight container 31 made of non-magnetic stainless steel with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35.

A pressure-resistant signal cable 36 containing a signal line for taking out a signal from the SQUID control system 35 is connected to the top portion of the highly pressure-resistant heatproof airtight container 31, and at the same time, a releasing tube 37 made of stainless steel for maintaining the pressure inside the highly pressure-resistant heatproof airtight container 31 is connected thereto.

Thus, the pressure-resistant signal cable 36 and the releasing tube 37 are separated, thereby making the configuration simple. As the probe depth gets deeper and the hanging length gets longer, however, arrangement becomes difficult. Therefore, this configuration is effective when the releasing tube is no longer than 1,000 m, typically no longer than 300 m, when the pressure-resistant performance is no higher than 10 MPa, typically no higher than 3 MPa.

FIG. 4 is a graph illustrating the results of calculation of the relationship between the inner diameter and the length of the releasing tube and the increase in the pressure due to the resistance of the evaporated nitrogen. When it is assumed that the temperature is maintained at 80 K or lower, it is necessary for the increase in the pressure to be no higher than 0.03 MPa (a pressure of 0.13 MPa), and therefore, it can be seen that it is indispensable for the releasing tube to have an inner diameter of approximately 7 mm for the length of 3,000 m.

In some cases, releasing tubes having such an inner diameter are difficult to handle such as when being rolled up, and therefore, it is also possible to combine a number of thinner tubes so as to obtain the corresponding cross-sectional area, which makes handling easy.

### EXAMPLE 2

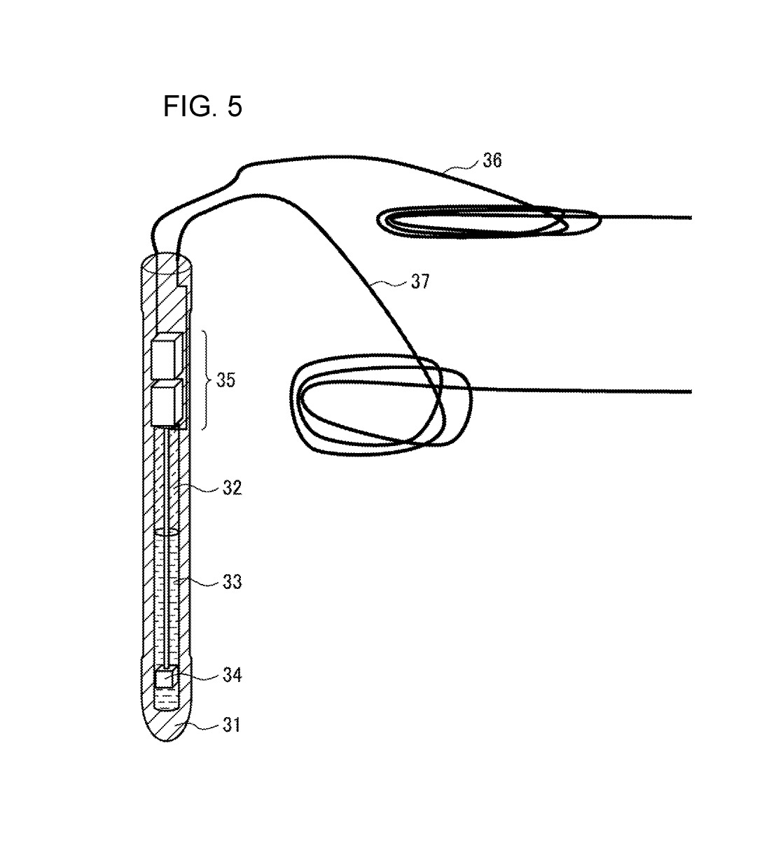

Next, the SQUID underground resource probing equipment according to Example 2 of the present invention is described in reference to FIG. 5. The example here is described under the assumption that the probe depth is 20 m to 1,000 m, and as an example where a pressure-resistant signal cable and a releasing tube are separated. FIG. 5 is a perspective diagram illustrating a main portion of the SQUID underground resource probing equipment according to Example 2 of the present invention, where a dewar for liquid nitrogen 32 made of Pyrex (registered trademark) is contained within a highly pressure-resistant heatproof airtight container 31 made of non-magnetic stainless steel with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35.

A pressure-resistant signal cable 36 containing a signal line for taking out a signal from the SQUID control system 35 is connected to the top portion of the highly pressure-resistant heatproof airtight container 31, and at the same time, a releasing tube 37 made of stainless steel for maintaining the pressure inside the highly pressure-resistant heatproof airtight container 31 is connected thereto.

In Example 2, a dewar of which the length is 10 or more times greater than the inner diameter is used as the dewar for liquid nitrogen 32. Thus, the use of a long and deep dewar makes it possible to reduce the heat influx and to cool the system for a long period of time with a small volume. For example, it was confirmed that liquid nitrogen was maintained for 30 hours or more in an experiment using a vacuum dewar made of Pyrex (registered trademark) having an inner diameter of 40 mm and a length of 500 mm. Thus, the use of a long and deep dewar reduces the amount of evaporation of liquid nitrogen, which reduces the increase in the pressure, and as a result, it becomes possible to reduce the diameter of the releasing tube.

### EXAMPLE 3

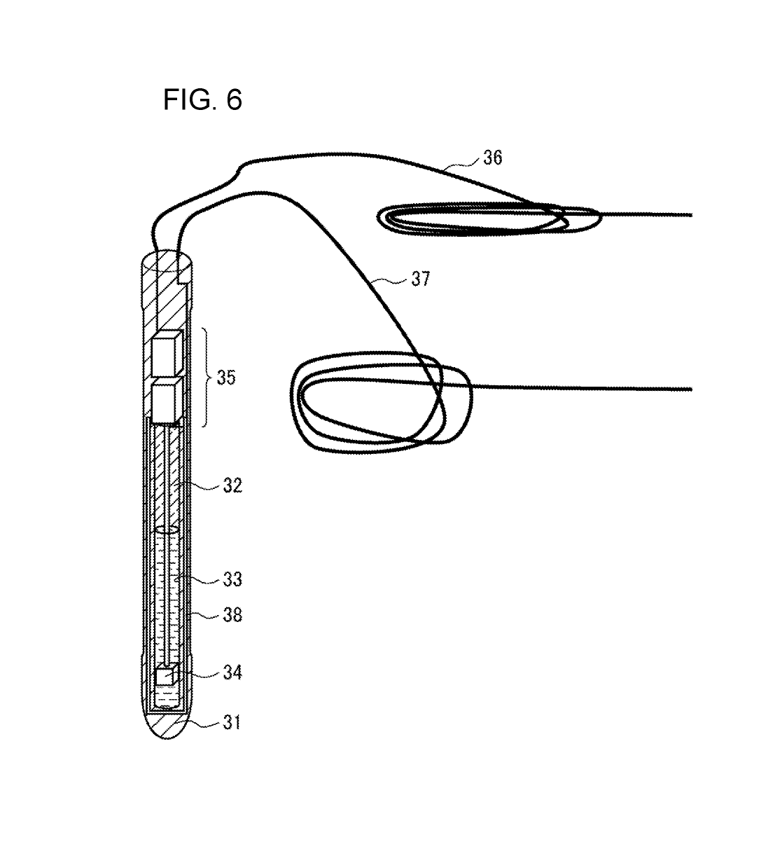

Next, the SQUID underground resource probing equipment according to Example 3 of the present invention is described in reference to FIG. 6. The example here is described under the assumption that the probe depth is 20 m to 1,000 m, and as an example where a pressure-resistant signal cable and a releasing tube are separated. FIG. 6 is a perspective diagram illustrating a main portion of the SQUID underground resource probing equipment according to Example 3 of the present invention, where a dewar for liquid nitrogen 32 made of Pyrex (registered trademark) is contained within a highly pressure-resistant heatproof airtight container 31 made of non-magnetic stainless steel with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35.

A pressure-resistant signal cable 36 containing a signal line for taking out a signal from the SQUID control system 35 is connected to the top portion of the highly pressure-resistant heatproof airtight container 31, and at the same time, a releasing tube 37 made of stainless steel for maintaining the pressure inside the highly pressure-resistant heatproof airtight container 31 is connected thereto.

In Example 3, an RF shield 38 is interposed between the protective interior made of plastic and the dewar for liquid nitrogen 32. In the case where a non-conductive material such as ceramic or plastic, or a highly resistant metal which easily allows the transmission of high frequency waves from a power transmission line or the like is used for the exterior of the highly pressure-resistant heatproof airtight container 31, it sometimes becomes difficult to operate the SQUID due to RF noise. In such a case, it is necessary to interpose an appropriate RF shield 38.

As for the material of the RF shield 38, a cloth coated with aluminum or plated with a metal (for example, Ni—Cu plating), a mesh formed of metal wires (such as of copper, silver or phosphor bronze), and the like can be used depending on the frequency to be shielded. Here, Ni—Cu plating is appropriate because it makes the generation of an induced current difficult.

### EXAMPLE 4

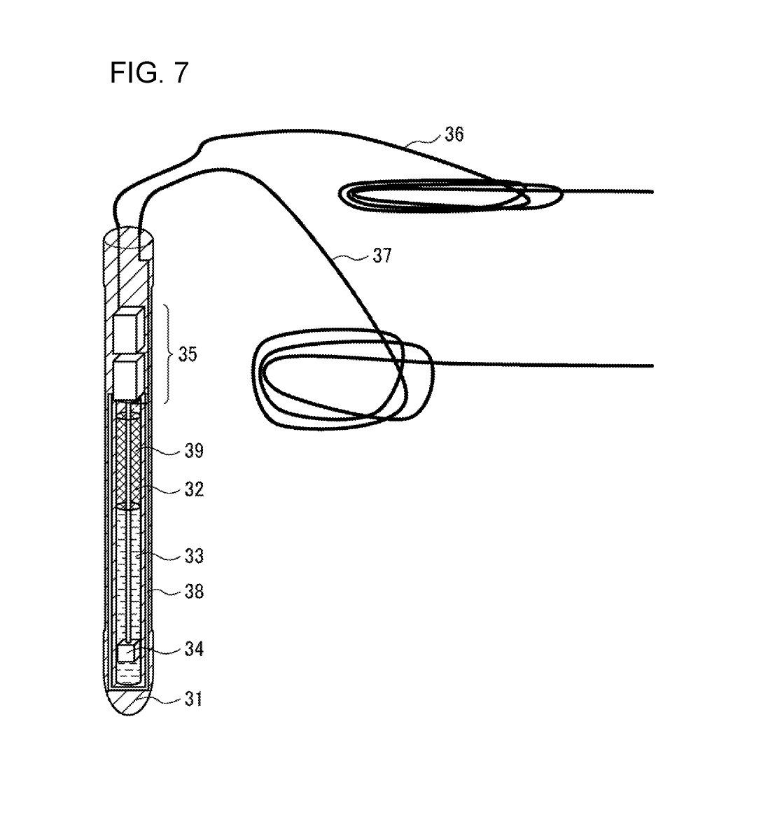

Next, the SQUID underground resource probing equipment according to Example 4 of the present invention is described in reference to FIG. 7. The example here is described under the assumption that the probe depth is 20 m to 1,000 m, and as an example where a pressure-resistant signal cable and a releasing tube are separated. FIG. 7 is a perspective diagram illustrating a main portion of the SQUID underground resource probing equipment according to Example 4 of the present invention, where a dewar for liquid nitrogen 32 made of Pyrex (registered trademark) is contained within a highly pressure-resistant heatproof airtight container 31 made of non-magnetic stainless steel with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35.

A pressure-resistant signal cable 36 containing a signal line for taking out a signal from the SQUID control system 35 is connected to the top portion of the highly pressure-resistant heatproof airtight container 31, and at the same time, a releasing tube 37 made of stainless steel for maintaining the pressure inside the highly pressure-resistant heatproof airtight container 31 is connected thereto. In addition, an RF shield 38 is interposed between the protective interior made of plastic and the dewar for liquid nitrogen 32.

In Example 4, a liquid nitrogen absorbent 39 is inserted into an upper portion of the inside of the dewar for liquid nitrogen 32. Though a polyvinyl alcohol (PVA) sponge is used as the liquid nitrogen absorbent, melamine foam may be used.

The liquid nitrogen absorbent is effective to easily prevent the liquid nitrogen 33 from spilling out from the dewar for liquid nitrogen 32 in the case where the container is inclined at the time of probing. In addition, the bubbling of evaporated nitrogen sometimes induces vibrations to the SQUID 34, which may cause noise. Such vibration noise particularly disturbs the measurement of low frequency waves. The contained liquid nitrogen absorbent 39 absorbs the vibrations due to bubbling, and thus has the effects of preventing noise from being generated.

### EXAMPLE 5

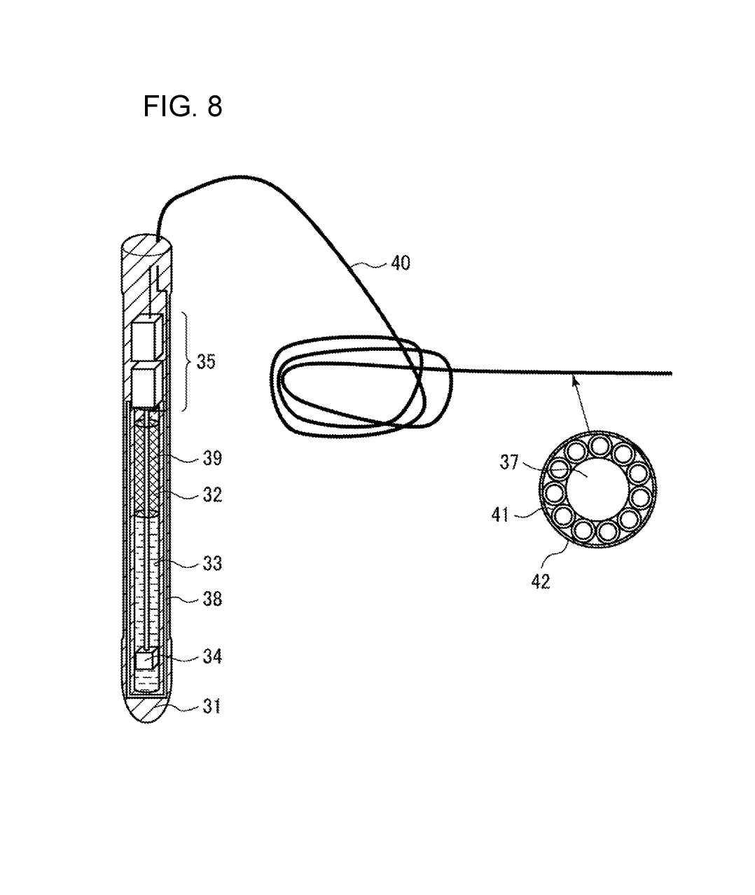

Next, the SQUID underground resource probing equipment according to Example 5 of the present invention is described in reference to FIG. 8. The example here is described under the assumption that the probe depth is 100 m to 2,000 m. FIG. 8 is a perspective diagram illustrating a main portion of the SQUID underground resource probing equipment according to Example 5 of the present invention, where a dewar for liquid nitrogen 32 made of Pyrex (registered trademark) is contained within a non-magnetic highly pressure-resistant heatproof airtight container 31 with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35. In addition, an RF shield 38 is interposed between the protective interior made of plastic and the dewar for liquid nitrogen 32, and at the same time, a liquid nitrogen absorbent 39 is inserted into an upper portion of the inside of the dewar for liquid nitrogen 32.

In Example 5, an armored cable 40 containing a releasing tube 37 inside is used as the pressure-resistant signal cable. It is necessary, for example, to use an armored cable of which the outer periphery is winded with a metal wire in order to hang a pressure-resistant container over 1,000 m for the transmission and the reception of a signal. The armored cable 40 has such a structure that signal wires 41 are arranged around a releasing tube 37, and the coating of the outer periphery of the signal wires 41 is winded with a metal wire 42.

The outer diameter of the armored cable 40 is approximately 30 mm to 60 mm, and the total thickness of the outer coating and the metal wire is approximately 3 mm. The pressure resistance of the releasing tube 37 increases as it is contained inside the armored cable 40.

### EXAMPLE 6

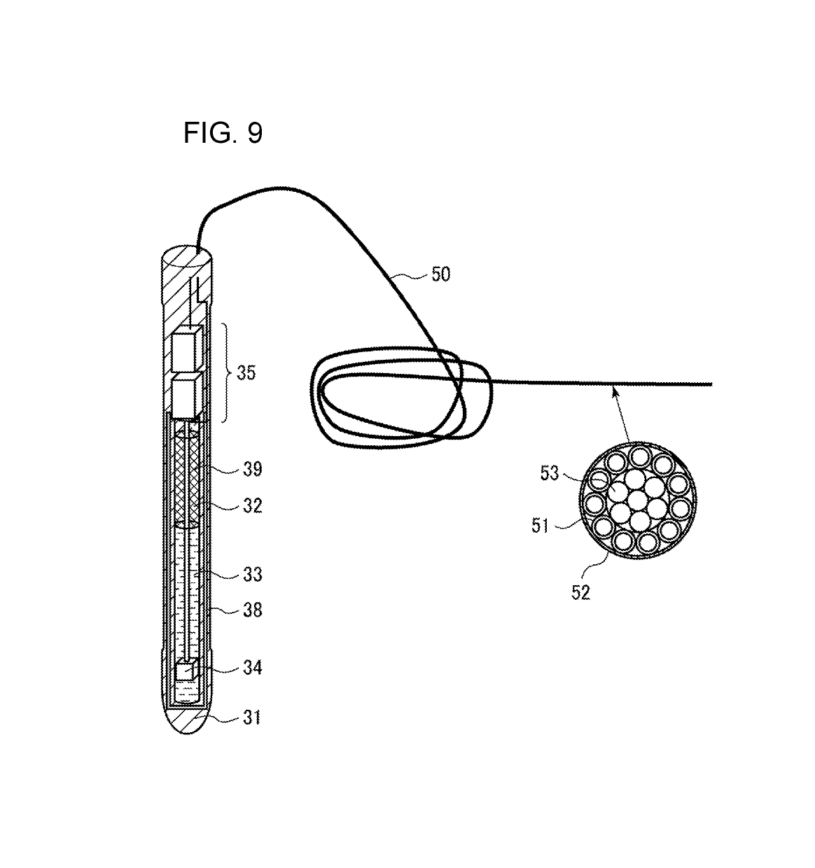

Next, the SQUID underground resource probing equipment according to Example 6 of the present invention is described in reference to FIG. 9. The example here is described under the assumption that the probe depth is 100 m to 3,000 m. FIG. 9 is a perspective diagram illustrating a main portion of the SQUID underground resource probing equipment according to Example 6 of the present invention, where a dewar for liquid nitrogen 32 made of Pyrex (registered trademark) is contained within a non-magnetic highly pressure-resistant heatproof airtight container 31 with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35. In addition, an RF shield 38 is interposed between the protective interior made of plastic and the dewar for liquid nitrogen 32, and at the same time, a liquid nitrogen absorbent 39 is inserted into an upper portion of the inside of the dewar for liquid nitrogen 32.

In Example 6, an armored cable 50 containing a number of releasing tubes 53 inside is used as the pressure-resistant signal cable. A typical structure provides a bundle of seven releasing tubes 53 made of stainless steel having an inner diameter of 2.4 mm. This structure makes it possible to further increase the pressure resistance performance while maintaining the flexibility as the pressure-resistant signal cable.

### EXAMPLE 7

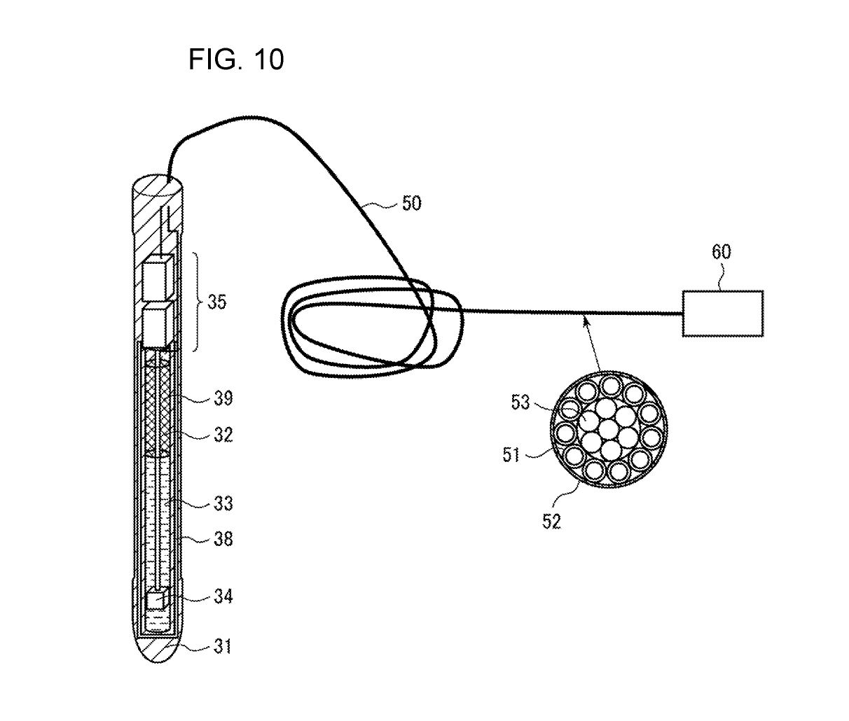

Next, the SQUID underground resource probing equipment according to Example 7 of the present invention is described in reference to FIG. 10. The example here is described under the assumption that the probe depth is 1,000 m to 4,000 m. FIG. 10 is a perspective diagram illustrating a main portion of the SQUID underground resource probing equipment according to Example 7 of the present invention, where a dewar for liquid nitrogen 32 made of Pyrex (registered trademark) is contained within a non-magnetic highly pressure-resistant heatproof airtight container 31 with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35.

In addition, an RF shield 38 is interposed between the protective interior made of plastic and the dewar for liquid nitrogen 32, and at the same time, a liquid nitrogen absorbent 39 is inserted into an upper portion of the inside of the dewar for liquid nitrogen 32.

In Example 7, an armored cable 50 containing a number of releasing tubes 53 is used as the pressure-resistant signal cable, where a vacuum pump 60 is connected to the armored tube 50 so that the inside of the releasing tubes 53 is maintained at a negative pressure.

In the case where the releasing tubes are long, the inner pressure may increase due to the resistance of the releasing tubes and the weight of the released gas, depending on the inner diameter of the releasing tube. In order to avoid this, it is necessary to maintain the inside of the release tubes at a negative pressure so as to enforce the discharge of the gas. As illustrated in FIG. 4, it is difficult to maintain the releasing tubes that exceed 1,000 m and of which the inner diameter is approximately 5 mm at 80 K or lower (0.13 MPa or lower) when the gas is simply released naturally. Therefore, the inside of the releasing tubes is maintained at a negative pressure so as to force the nitrogen gas to be released.

Here, a rotary pump or a booster vacuum pump is used as the vacuum pump 60. Though there is a demerit in that booster vacuum pumps are large in size as compared to conventional rotary pumps, it is possible to provide a large amount of discharge, and thus, a booster vacuum pump is effective in the case where the releasing tubes are long.

### EXAMPLE 8

Next, the SQUID underground resource probing equipment according to Example 8 of the present invention is described in reference to FIGS.

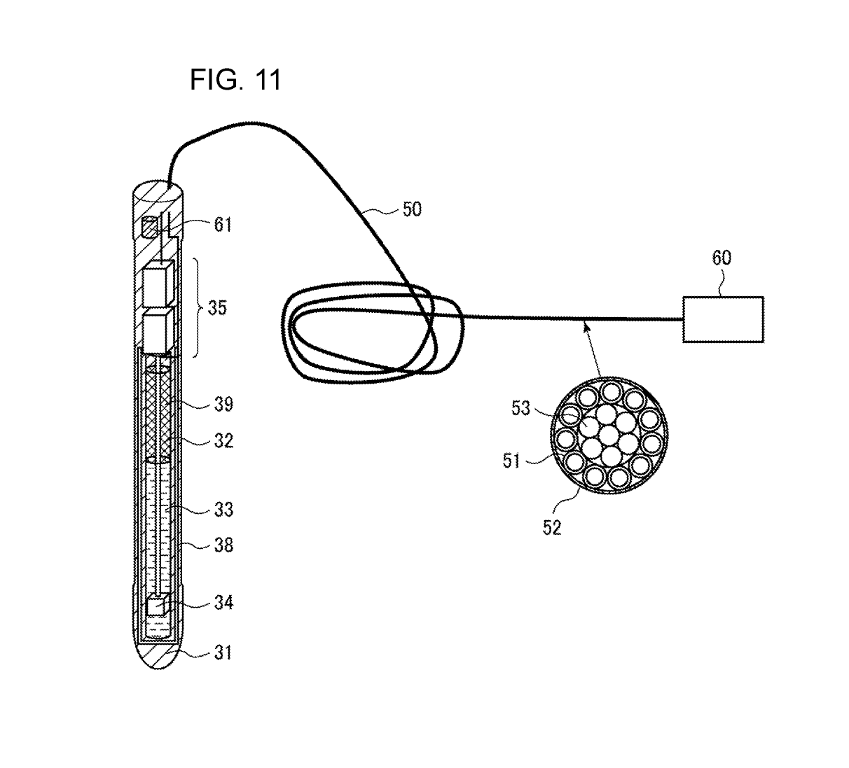

11 and 12. The example here is described under the assumption that the probe depth is 1,000 m to 4,000 m. FIG. 11 is a perspective diagram illustrating a main portion of the SQUID underground resource probing equipment according to Example 8 of the present invention, where a dewar for liquid nitrogen 32 made of Pyrex (registered trademark) is contained within a non-magnetic highly pressure-resistant heatproof airtight container 31 with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35.

In addition, an RF shield 38 is interposed between the protective interior made of plastic and the dewar for liquid nitrogen 32, and at the same time, a liquid nitrogen absorbent 39 is inserted into an upper portion of the inside of the dewar for liquid nitrogen 32. Furthermore, an armored cable 50 containing a number of releasing tubes 53 is used as the pressure-resistant signal cable, where a vacuum pump 60 is connected to the armored tube 50 so that the inside of the releasing tubes 53 is maintained at a negative pressure.

In Example 8, the pressure within the highly pressure-resistant heatproof airtight container 31 is monitored by a pressure gauge 61 provided within the highly pressure-resistant heatproof airtight container 31, and the detection output of the pressure gauge 61 allows the amount of vacuum pump suction to be controlled so that the inner temperature can be controlled with precision and the temperature inside the highly pressure-resistant heatproof airtight container 31 can be maintained at a constant.

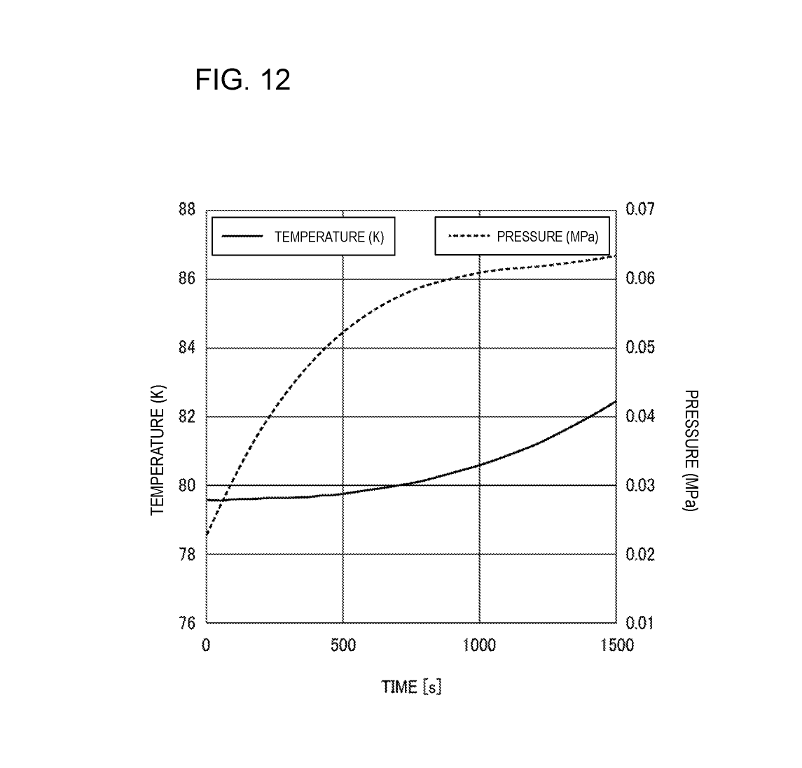

FIG. 12 is a graph illustrating the time difference between the increase in the pressure and the increase in the temperature, where the increase in the temperature of the liquid nitrogen is delayed relative to the increase in the pressure because of the heat capacity of the liquid nitrogen. Therefore, the feedback from the pressure monitoring is effective for a more delicate temperature control rather than the feedback from the temperature monitoring. In this case, however, the internal structure needs to be devised in such a manner that the pressure monitoring allows for the measurement of the differential pressure vis-à-vis the atmospheric pressure, and thus, there is a demerit that the structure is complicated as compared to that in the case of the feedback from the temperature monitoring.

### EXAMPLE 9

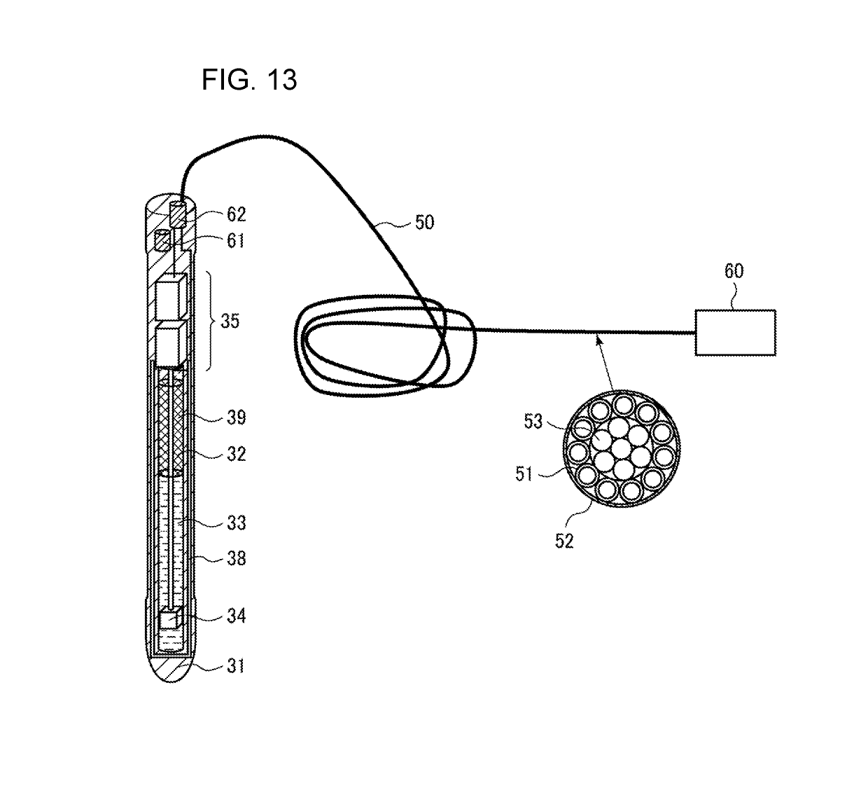

Next, the SQUID underground resource probing equipment according to Example 9 of the present invention is described in reference to FIG. 13. The example here is described under the assumption that the probe depth is 1,000 m to 4,000 m. FIG. 13 is a perspective diagram illustrating a main portion of the SQUID underground resource probing equipment according to Example 9 of the present invention, where a dewar for liquid nitrogen 32 made of Pyrex (registered trademark) is contained within a non-magnetic highly pressure-resistant heatproof airtight container 31 with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35.

In addition, an RF shield 38 is interposed between the protective interior made of plastic and the dewar for liquid nitrogen 32, and at the same time, a liquid nitrogen absorbent 39 is inserted into an upper portion of the inside of the dewar for liquid nitrogen 32. Furthermore, an armored cable 50 containing a number of releasing tubes 53 is used as the pressure-resistant signal cable, where a vacuum pump 60 is connected to the armored tube 50 so that the inside of the releasing tubes 53 is maintained at a negative pressure.

In Example 9, the pressure within the highly pressure-resistant heatproof airtight container 31 is monitored by a pressure gauge 61 provided within the highly pressure-resistant heatproof airtight container 31, and the detection output of the pressure gauge 61 allows a pressure adjusting valve 62 made of an electromagnetic valve to be operated so that the inner pressure and the temperature of the highly pressure-resistant heatproof airtight container 31 can be maintained at a constant.

This configuration makes quick feedback possible as compared to a case of control by sending a feedback signal to an external pump, for example, and thus is effective in the control of the system in the case where a releasing tube that exceeds 2,000 m is necessary. In addition, the danger of such an accident where water gets into the highly pressure-resistant heatproof airtight container 31 increases when the environmental pressure increases. The mechanism that allows the pressure adjusting valve 62 to open at the time of an emergency so that the pressure can be forced to be negative is useful to maintain safety.

### EXAMPLE 10

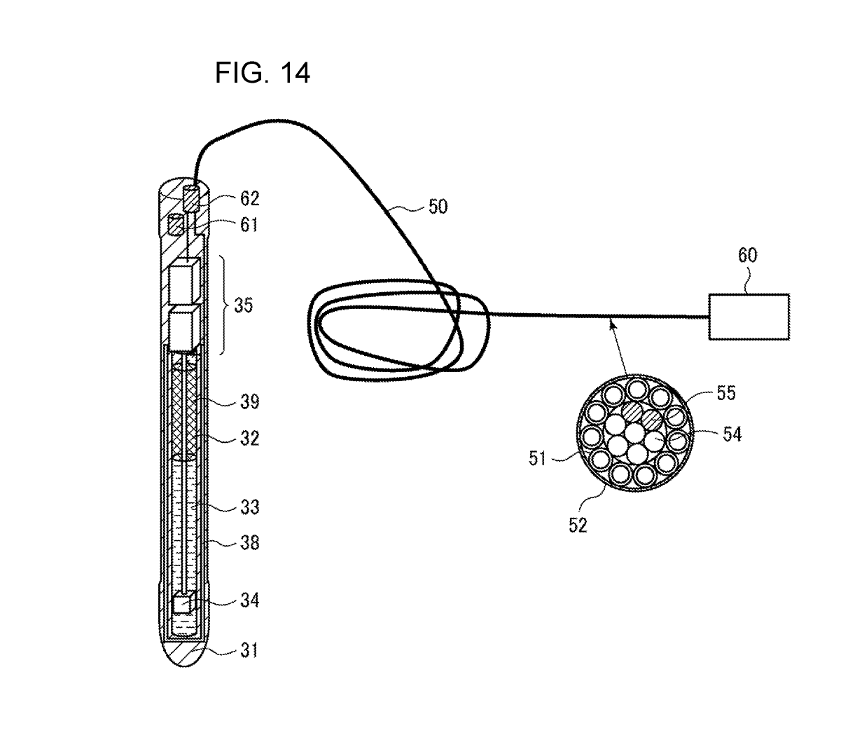

Next, the SQUID underground resource probing equipment according to Example 10 of the present invention is described in reference to FIG. 14. The example here is described under the assumption that the probe depth is 1,000 m to 4,000m. FIG. 14 is a perspective diagram illustrating a main portion of the SQUID underground resource probing equipment according to Example 10 of the present invention, where a dewar for liquid nitrogen 32 made of Pyrex (registered trademark) is contained within a non-magnetic highly pressure-resistant heatproof airtight container 31 with a protective interior made of plastic (not shown) in between. The dewar for liquid nitrogen 32 is filled in with liquid nitrogen 33, a SQUID 34 is immersed in the liquid nitrogen 33, and the SQUID 34 is connected to a SQUID control system 35.

In addition, an RF shield 38 is interposed between the protective interior made of plastic and the dewar for liquid nitrogen 32, and at the same time, a liquid nitrogen absorbent 39 is inserted into an upper portion of the inside of the dewar for liquid nitrogen 32. Furthermore, an armored cable 50 containing a number of releasing tubes 53 is used as the pressure-resistant signal cable, where a vacuum pump 60 is connected to the armored tube 50 so that the inside of the releasing tubes 53 is maintained at a negative pressure.

In addition, the pressure within the highly pressure-resistant heatproof airtight container 31 is monitored by a pressure gauge 61 provided within the highly pressure-resistant heatproof airtight container 31, and the detection output of the pressure gauge 61 allows a pressure adjusting valve 62 made of an electromagnetic valve to be operated so that the inner pressure and the temperature of the highly pressure-resistant heatproof airtight container 31 can be maintained at a constant.

In Example 10, from among the releasing tubes in the structure, some releasing tubes 54 are in an open state and the other releasing tubes 55 are maintained at a negative pressure. For example, five releasing tubes 54 out of seven releasing tubes are in an open state all the time while two releasing tubes 55 are maintained at a negative pressure.

In the case where the inner diameter of the releasing tubes 54 and 55 is 2.4 mm, for example, five releasing tubes 54 having a length of 3,000 m can maintain the inside at 80 K or lower when the amount of evaporation of nitrogen is 8.2×10⁻⁶ m³/s. However, a case can be assumed where the discharge of gas cannot catch up with the increase in the temperature that is forced by the heater for releasing the magnetic flux trap in the SQUID or the dramatic increase in the amount of evaporation due to an accident. In such cases, the releasing tubes 55 maintained at a negative pressure can be used as bypass releasing tubes for adjusting the inner pressure so as to handle the increase in the inner pressure quickly. This structure is useful not only for the maintenance of the temperature, but also for increasing the safety of the equipment.

Though it is also possible to forcefully open the pressure adjusting valve 62 from aboveground, feedback control by means of the pressure gauge 61 provided inside is also possible. In addition to an electromagnetic valve, a spring-type valve that automatically opens or closes in response to a certain difference in pressure can be used as the pressure adjusting valve 62, and in this case, the structure of the valve can be made simple and can be easily made of a non-magnetic material through the control of the pressure within the releasing tubes.

Though the depth applied for each example is shown as a standard in the above-described examples, a probing equipment for a deep depth may of course be used for probing at a shallow depth. Though it is not mentioned to plate in the vacuum layer on the inside of the dewar for liquid nitrogen in each of the above-described embodiments, plating may of course be done.

As for the RF shield or the liquid nitrogen absorbent provided in the latter examples in addition to the respective features, they may be used if necessary and are not essential. In addition, a thermometer, a water leak detector and the like may also be provided if necessary.

### REFERENCE SIGNS LIST

10 highly pressure-resistant cooling container for a sensor
11 pressure-resistant airtight container
12 protective interior
13 phase transition cooling insulating container
14 thermometer
15 pressure sensor
16 water leak detector
17 tube for releasing a phase transition coolant
18 phase transition coolant
21 sensor
22 cable for inputting/outputting a signal
23 sensor control system
31 highly pressure-resistant heatproof airtight container
32 dewar for liquid nitrogen
33 liquid nitrogen
34 Squid
35 Squid control system
36 pressure-resistant signal cable
37 releasing tube
38 RF shield
39 liquid hydrogen absorbent
40, 50 armored cable
41, 51 signal line
42, 52 metal wire
53, 54, 55 releasing tube
60 vacuum pump
61 pressure gauge
62 pressure adjusting valve

1-13. (canceled)

14. A highly pressure-resistant cooling container for a sensor comprising:
a pressure-resistant airtight container having a pressure-resistance performance of 1.0 MPa or higher;
a phase transition coolant insulating container contained within the pressure-resistant airtight container; and
a tube for releasing a phase transition coolant having a pressure-resistance performance of 1.0 MPa or higher and connected to the pressure-resistant airtight container;
a pressure-resistance exterior for implementing the pressure-resistance performance of 1.0 MPa or higher;
a sealing material for sealing the pressure-resistant airtight container; and
a protective interior provided within the pressure-resistant airtight container, wherein the pressure-resistance exterior, the sealing material and the protective interior are made of a non-magnetic material having heat resistance of 200° C. or higher.

15. The highly pressure-resistant cooling container for a sensor according to claim 14, wherein the phase transition coolant is liquid nitrogen, and the sensor is a high temperature superconducting SQUID.

16. The highly pressure-resistant cooling container for a sensor according to claim 14, wherein the phase transition coolant insulating container is a vacuum dewar made of glass of which the length is 10 to 50 times greater than the inner diameter.

17. The highly pressure-resistant cooling container for a sensor according to claim 14, wherein an RF shield for shielding a high frequency of 50 KHz or higher is provided inside the pressure-resistant airtight container.

18. The highly pressure-resistant cooling container for a sensor according to claim 17, wherein the RF shield is made of an Ni—Cu plating.

19. The highly pressure-resistant cooling container for a sensor according to claim 14, wherein a phase transition coolant absorbent is provided inside the phase transition coolant insulating container.

20. The highly pressure-resistant cooling container for a sensor according to claim 14, wherein the tube for releasing a phase transition coolant is an aggregate of a number of tubes.

21. The highly pressure-resistant cooling container for a sensor according to claim 14, further comprising a cable for inputting/outputting a signal connected to the pressure-resistant airtight container so that the tube for releasing a phase transition coolant is contained in the cable for inputting/outputting a signal.

22. The highly pressure-resistant cooling container for a sensor according to claim 14, further comprising a pressure-maintaining mechanism for maintaining the pressure inside the tube for releasing a phase transition coolant at a negative pressure relative to the pressure within the pressure-resistant airtight container and for maintaining the pressure within the pressure-resistant airtight container at 0.04 MPa to 0.13 MPa.

23. The highly pressure-resistant cooling container for a sensor according to claim 22, further comprising a pressure sensor inside the pressure-resistant airtight container, wherein
the pressure-maintaining mechanism is a mechanism that maintains the temperature of the pressure-resistant airtight container at a constant through the control of feeding back the detected output from the pressure sensor.

24. The highly pressure-resistant cooling container for a sensor according to claim 23, wherein the pressure-maintaining mechanism comprising:
a decompression mechanism for maintaining at a negative pressure in advance the inside of the tube for releasing a phase transition coolant; and
an opening and closing mechanism for opening and closing a valve provided in the tube for releasing a phase transition coolant.

25. The highly pressure-resistant cooling container for a sensor according to claim 24, further comprising a cable for inputting/outputting a signal connected to the pressure-resistant airtight container, wherein
the cable for inputting/outputting a signal contains a number of tubes for releasing a phase transition coolant, each of which has the same structure as the tube for releasing a phase transition coolant, in such a manner that
one tube for releasing a phase transition coolant is in a such a state as to be open to the air all the time, and
another tube for releasing a phase transition coolant has the inside maintained at a negative pressure and is connected to the inside of the pressure-resistant airtight container via a valve.

26. An underground probing equipment comprising:
the pressure-resistant cooling container for a sensor according to claim 14; and
a sensor immersed in the phase transition coolant.
